(19) United States
(12) Patent Application Publication
(10) Pub. No.: US 2025/0070766 A1
(43) Pub. Date: Feb. 27, 2025

(54) OPTICALLY SUPPLIED POWER TO A POWER ELECTRONICS SUPPORTING CIRCUIT

(71) Applicant: Eaton Intelligent Power Limited, Dublin 4 (IE)

(72) Inventor: Geraldo NOJIMA, Arden, NC (US)

(21) Appl. No.: 18/813,720

(22) Filed: Aug. 23, 2024

Related U.S. Application Data
(60) Provisional application No. 63/534,446, filed on Aug. 24, 2023.

(51) Int. Cl. H03K 3/42; H01S 5/062

(52) U.S. Cl. CPC H03K 3/42; H01S 5/062

(57) ABSTRACT

A method to provide power to a control supporting circuit includes connecting an optical power converter to the control support circuit, the optical power converter connected to a laser source via a fiber optic cable, controlling, by a controller, a laser source driver to drive a laser source providing a laser and the control supporting circuit; and supplying power to the control supporting circuit by irradiating the optical power converter with the laser via the fiber optic cable. A stray capacitance between the controller and the high voltage supporting circuit is reduced to zero or nearly zero. A method of shutting down a laser source driver providing laser energy to an optical power converter is also provided.

### CROSS REFERENCE TO RELATED APPLICATION

This application claims the benefit of U.S. Provisional Application No. 63/534,446 filed Aug. 24, 2023.

### STATEMENT REGARDING GOVERNMENT FUNDING

This invention was made with Government support under government contract DOE contract number DE-EE0009135. The Federal Government has certain rights to this invention.

### BACKGROUND

In power electronics, voltages are transformed by converter circuits, which are then coupled to other components through buses or other interconnecting or interfacing structures. Traditionally, silicon-based semiconductors have been used heavily in such converter circuits, however, wide-Bandgap and Ultrawide-Bandgap semiconductors are seeing increasing use in converter circuits due to their many superior physical traits, including operation in wider temperatures, voltages, and frequencies. These wide-Bandgap and Ultrawide Bandgap semiconductors can reach switching speeds that are at least one order of magnitude higher than that of the silicon-based semiconductors. To cope with the faster wide-bandgap and ultrawide bandgap semiconductor transistors, such as silicon carbide MOSFET, a converter circuit has to have significantly reduced parasitic components (e.g., components that introduce inductance and capacitance) by at least ten times.

### BRIEF SUMMARY

Methods to provide power to a low voltage control supporting circuit that is connected to a high voltage system by utilizing an optical power supply are provided. In addition, a method to shut down a laser source when the fiber optic cable is broken is provided. The described method is suitable to provide power to low voltage control supporting circuits connected to power electronics circuits incorporating wide bandgap (silicon carbide-SiC) and ultrawide bandgap (diamond) MOSFET switches. In some cases, the described method is suitable for high voltage power electronics in the voltage range of 0.6 kV to 1,000 kV. Accordingly, high voltage as used herein are at and above 600V. Advantageously, it is possible to eliminate the coupling components between the controller and the control supporting circuit that is connected to the high voltage system by replacing a conventional power supply comprising a transformer that includes a stray capacitance with an optical power supply.

A method to provide power to a control supporting circuit that is connected to a high voltage system includes connecting an optical power converter by a fiber optic cable between a controller and the high voltage supporting circuit, the controller providing control signals to a laser source driver to drive a laser source providing a laser and providing control signals to the high voltage supporting circuit; and supplying power to the high voltage supporting circuit by irradiating the optical power converter with the laser via the fiber optic cable. A stray capacitance between the controller and the high voltage supporting circuit is reduced to zero or nearly zero such that the stray capacitance is sufficiently low to not affect operation of the high voltage support circuit.

A method of shutting down a laser source driver providing laser energy to an optical power converter includes connecting an optical power converter by a fiber optic cable between a controller and a high voltage supporting circuit, the controller providing control signals to a laser source driver to drive a laser source providing a laser and providing control signals to a high voltage supporting circuit, supplying power to the high voltage supporting circuit by irradiating the optical power converter with the laser via the fiber optic cable; connecting a second fiber optic cable from the controller to the high voltage supporting circuit; and monitoring a feedback signal from the high voltage supporting circuit to the controller on the second fiber optic cable. Responsive to detecting a loss of the feedback signal, turning off, by the controller, the laser source driver.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

FIG. 1 illustrates a schematic diagram of an operating environment for a conventional control supporting circuit coupled to a power electronics circuit.

FIG. 2 illustrates a schematic diagram of an example operating environment of a control supporting circuit coupled to a power electronics circuit including an optical power supply.

FIG. 3 illustrates an optical power supply.

FIG. 4 illustrates a cross-sectional view of the optical power supply of FIG. 2 and FIG. 3.

FIG. 5 illustrates a process flow describing a method of providing power to a control supporting circuit according to one embodiment.

FIG. 6 illustrates a process flow describing a method of shutting down a laser source driver providing laser energy to an optical power converter according to one embodiment.

### DETAILED DESCRIPTION

A method to provide power to a control supporting circuit connected to a high voltage system utilizing an optical power supply is provided. The described method is suitable to provide power to low voltage control supporting circuits connected to power electronics circuits incorporating wide bandgap (silicon carbide-SiC) and ultrawide bandgap (diamond) MOSFET switches. In some cases, the described method is suitable for high voltage power electronics in the voltage range of 0.6 kV to 1000 kV. Accordingly, high voltage as used herein are at and above 600V. Advantageously, it is possible to eliminate the parasitic components between the controller and the high voltage supporting circuit by replacing a conventional power supply comprising a transformer that includes a stray capacitance with an optical power supply.

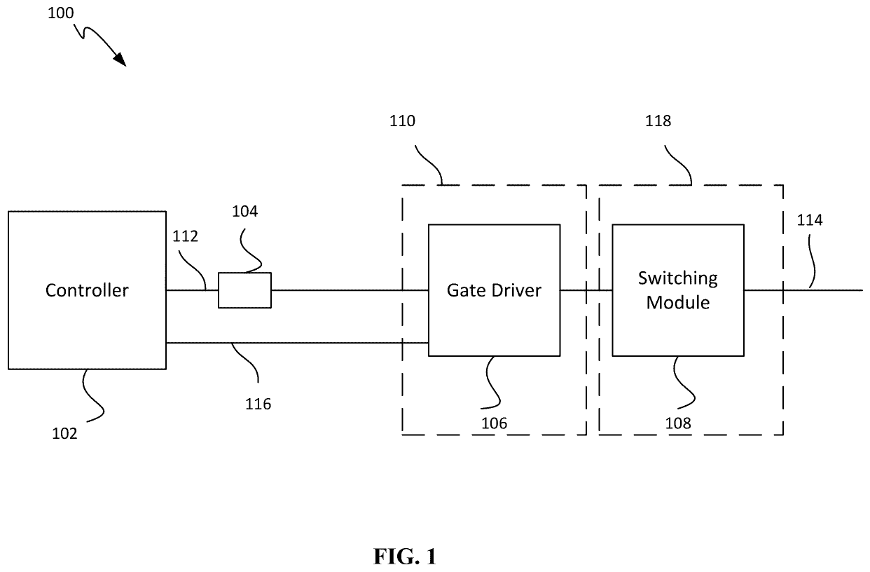

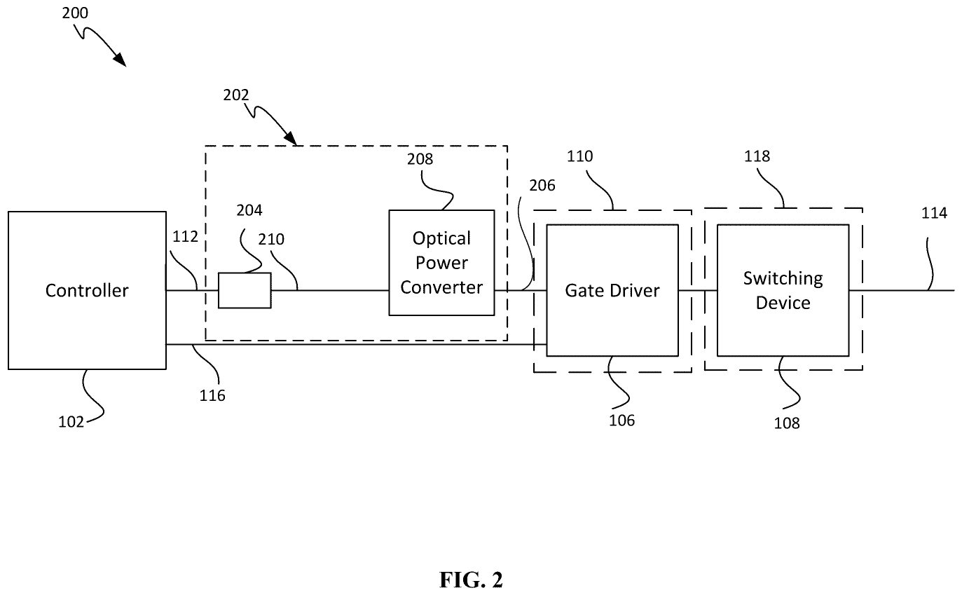

FIG. 1 illustrates a schematic diagram of an operating environment for a conventional control supporting circuit coupled to a power electronics circuit. In the embodiments shown in FIG. 1 and FIG. 2, the control supporting circuit is connected to a high voltage power electronics circuit. While a power electronics circuit is being described in this disclosure, other key control systems such as feedback generation circuits for voltage, current and temperature signals can be the circuit that the control supporting circuit is connected to.

Referring to FIG. 1, operating environment 100 includes a controller 102, a power supply 104, and a control supporting circuit 110 connected to a power electronics circuit 118. Controller 102 provides control signals for the control of control supporting circuit 110 through line 116 and provides control signals for the control of power supply 104 through cable 112. A power supply 104 provides power (e.g., AC or DC) to the control supporting circuit 110 via cable 112. The control supporting circuit 110 outputs power (e.g., AC or DC) via output line 114 that can be provided to any outside elements such as, for example, a motor, an actuator, or a solenoid.

The control supporting circuit 110 comprises a low voltage gate driver 106. The power electronics circuit 118 comprises switching module 108. Gate driver 106 is coupled to the switching module 108. Controller 102 sends a signal to the gate driver 106 to drive the switching module 108 via line 116. In some cases, the switching module 108 can include at least one wide bandgap transistor. In other cases, the switching module 108 can include at least one ultrawide bandgap transistor. However, for exemplary purposes, the switching module 108, as discussed herein, includes at least one wide bandgap transistor. In some cases, the switching module 108 includes multiple wide bandgap transistors. For example, 72 MOSFET devices can be used for a 15 KV RMS (root means square) bi-directional converter. Gate driver 106 is a circuit used to produce a high current drive input for the gate of the at least one wide bandgap transistor on the switching module 108. Through the control signals of the controller 102, the gate driver 106 switches on and off the wide bandgap transistor(s) on the switching module 108. The wide bandgap transistors on the switching module 108 are designed for breakdown voltages of up to 20 kV and switching frequencies between 5 kHz and 10 kHz. In an embodiment, the wide bandgap transistors on the switching module 108 are designed for a breakdown voltage of 10 kV at a switching frequency of 10 kHz.

As the switching speeds of the wide bandgap transistors are much faster than silicon semiconductors, the transition rate, e.g., the rate of change of the voltage, for the switching module 108 can go up to 240 kV per microsecond when the switching module 108 is switched on or switched off. At this transition rate, the parasitic losses are much higher than desired. It is desired, then, to limit the transition rate to 60 kV. The transition rate when the control supporting circuit 110 transitions from off to the operating voltage and vice versa, from operating voltage to off, can be higher than 100 kV per microsecond which can create an uncontrolled oscillatory response, instability, and EMI (Electromagnetic Interference) in the power electronics circuit 118. These effects can be difficult to mitigate in controller 102.

In some cases, the switching module 108 can comprise a first switching module and a second switching module connected in series to create a switching device of higher voltage capacity (up to 16 kV) than single switching modules. In some cases, the switching module 108 can comprise multiple (more than two) switching modules connected in series. The transition rate, then, with the first switching module and the second switching module connected in series, when limited to 60 kV, is 120 kV with the result that EMI well over an acceptable limit is generated in the controller 102.

For example, in a typical control supporting circuit 110, the power supply 104 comprises a transformer having a primary and a secondary winding forming a capacitor with a capacitance of approximately 5 pF. While 5 pF is a relatively small capacitance, when utilizing many wide bandgap transistors, for example 72 transistors on the switching module 108, a very large current can result producing EMI over the acceptable limit. Thus, in order to reduce the EMI generated, the stray capacitance between the controller 102 and the control supporting circuit 110 can be reduced and/or eliminated.

In order to eliminate the stray capacitance between the control supporting circuit 110 and the controller 102, it is thus proposed to connect an optical power supply between the control supporting circuit 110 and the controller 102 to supply optical power to the control supporting circuit 110.

FIG. 2 illustrates a schematic diagram of an example operating environment of a control supporting circuit coupled to a power electronics circuit including an optical power supply. Referring to FIG. 2, operating environment 200 includes controller 102, an optical power supply 202, control supporting circuit 110, and power electronics circuit 118. Optical power supply 202 includes laser source 204 and optical power converter 208. Laser source 204 is coupled to the controller 102 by cable 112. Optical power supply 202 replaces power supply 104 in FIG. 1 to provide optically supplied power to the control supporting circuit 110. In some cases, controller 102 includes a laser source driver to control the laser source 204. In other cases, the laser source driver can be a separate circuit coupled to optical power supply 202 to control the laser source 204. Optical power converter 208 is coupled to the laser source 204 by a fiber optic cable 210. In some cases, line 116 connecting the controller 102 to the gate driver 106 can be a second fiber optic cable that communicates commands to/from the controller 102 to/from the gate driver 106.

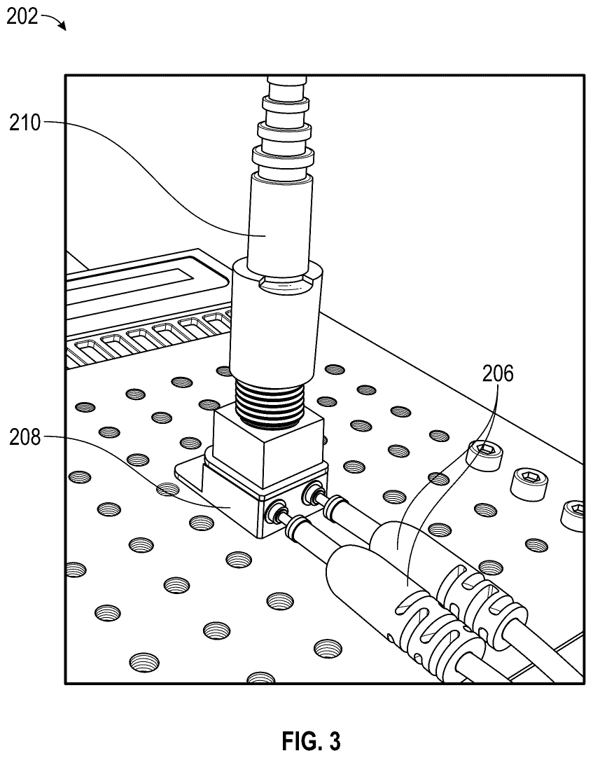

FIG. 3 illustrates an optical power supply according to an embodiment. Optical power supply 202 comprises laser source 204 (shown in FIG. 1), fiber optic cable 210, an optical power converter 208, and leads 206. Laser source 204 is coupled to optical power converter 208 by the fiber optic cable 210. Optical power supply 202 is powered by laser source driver (not shown). The optical power converter 208 comprises a semiconductor device that when irradiated by the laser, converts the laser energy provided by the laser into electrical energy. The optical power converter 208 is irradiated by the laser via the fiber optic cable 210 which carries the optical power. In some cases, the fiber optic cable 210 comprises a glass fiber optic cable. Fiber optic cable 210 can be up to 100 m long. The optical power supply 202 generates 12V-20V at 5 W to the control supporting circuit 110 via leads 206. Leads 206 include a positive and negative terminal to supply 12-20V at 5 W to the control supporting circuit 110.

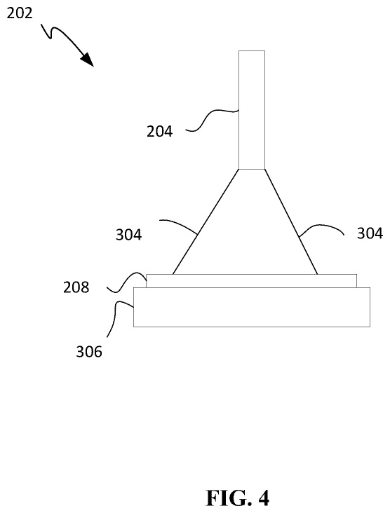

FIG. 4 illustrates a cross sectional view of the optical power supply of FIG. 2 and FIG. 3. Laser source 204 provides a laser 304 as the energy transporting medium via the fiber optic cable 210 (as shown in FIG. 2). In some cases, the laser source 204 is a semiconductor diode that provides 10 W to 20 W power to the optical power converter 208. Laser source 204 can be tuned to the wavelength utilized by the optical power converter 208. The laser 304 irradiates optical power converter 208 which converts the optical power to electrical power which can then be provided to the control supporting circuit 110. The optical power converter 208 can capture optical energy at approximately 50% efficiency. Optical power supplied by a glass fiber optic cable 210, for example, provides galvanic, electromagnetic and electrostatic isolation to the controller 102 allowing controller 102 to operate like a “bird on a wire”.

Because the optical power converter 208 receives 10 W to 20 W power, it will generate a considerable amount of heat that needs to be drawn out of the semiconductor device. Therefore, the optical power converter 208 can be disposed adjacent to a heat sink 306 that draws the heat away from the optical power converter 208.

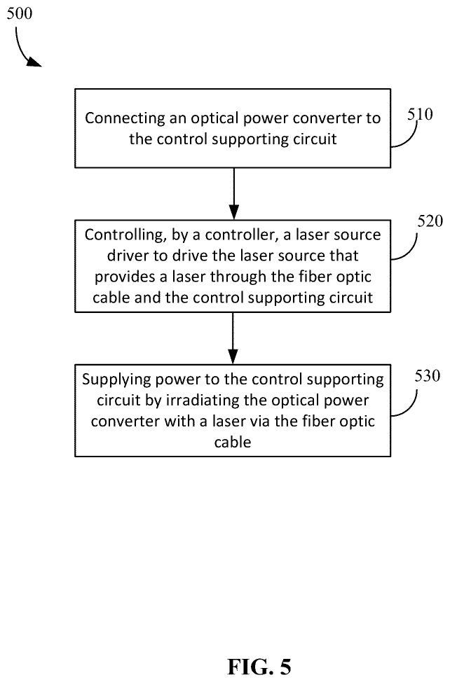

FIG. 5 illustrates a process flow describing a method of providing power to a control supporting circuit according to one embodiment. Method 500 is performed to provide power to control supporting circuit 110. Referring to FIG. 5, method 500 includes connecting (510) an optical power converter to the control supporting circuit. The optical power converter is connected to a laser source via a fiber optic cable. Method 500 further includes (520) controlling, by the controller, a laser source driver to drive a laser source providing a laser through the fiber optic cable and the control supporting circuit. Method 500 also includes supplying (530) power to the control supporting circuit by irradiating the optical power converter with the laser via the fiber optic cable.

In the case that the fiber optic cable 210 is ever cut for the above-described system, e.g., an optical power supply powering a control supporting circuit, the laser energy could be concentrated on a very small area and damage the surrounding components and/or a person in the line of the laser energy. For this reason, a method to shut down the laser source driver is proposed.

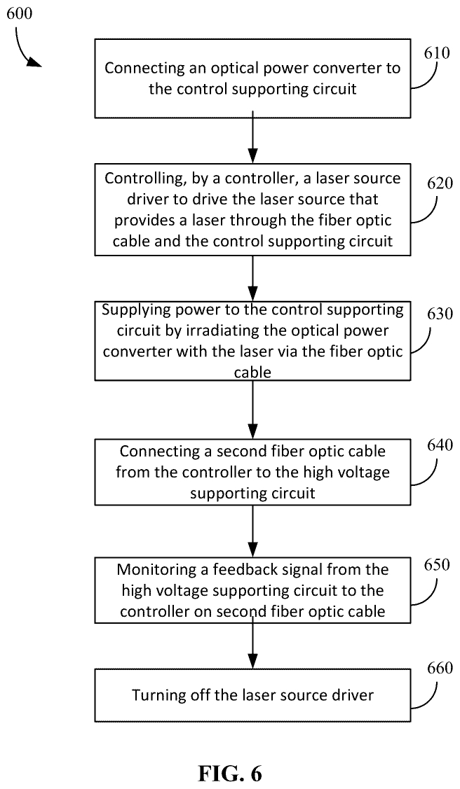

FIG. 6 illustrates a process flow describing a method for shutting down a laser source driver providing laser energy to an optical power converter. Method 600 is performed to shut down a laser source driver when a fiber optic cable carrying fiber energy via the fiber optic cable is cut. Referring to FIG. 6, method 600 includes connecting (610) an optical power converter to a control supporting circuit. The optical power converter is connected to a laser source via a fiber optic cable. The control supporting circuit can be the gate driver shown in FIG. 1 and FIG. 2. Method 600 further includes (620) controlling, by the controller, a laser source driver to drive a laser source providing a laser through the fiber optic cable and the control supporting circuit. Method 600 further includes supplying (630) power to the control supporting circuit by irradiating the optical power converter with the laser via the fiber optic cable. Method 600 further includes connecting (640) a second fiber optic cable from the controller to the high voltage supporting circuit. Method 600 further includes monitoring (650) a feedback signal from the control supporting circuit to the controller on the second fiber optic cable. When a loss of the feedback signal is detected, the controller turns off the laser source driver (660).

Controller 102, which generates the command signals to the gate driver 106, receives a feedback signal (e.g., comprising light) via the second fiber optic cable 116 (e.g., line 116) as a confirmation of signals sent to the gate driver 106 and includes short-circuit fault status. The feedback signal (e.g., the light signal) is usually turned on, however, if it turns off for more than a certain amount of time (generally less than a few microseconds) a fault state is issued and the controller 102 shuts down the system safely. In some cases, the shutdown of the laser source driver providing laser energy occurs in less than 10 μs to limit the amount of uncontrolled laser energy that is injected in the surrounding environment in case the fiber optic cable 210 is cut. In order to shutdown the laser source driver at the fastest rate possible to avoid a broken laser path, a crowbar circuit can be used coupled to the laser source to shunt the terminals of the laser source 204.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims and other equivalent features and acts are intended to be within the scope of the claims.

What is claimed is:

1. A method to provide power to a control supporting circuit that is coupled to a high voltage system, comprising:
connecting an optical power converter to the control supporting circuit that is coupled to the high voltage system, wherein the optical power converter is connected to a laser source via a fiber optic cable;
controlling, by a controller, a laser source driver to drive the laser source that provides a laser through the fiber optic cable;
controlling, by the controller, the control supporting circuit; and
supplying power to the control supporting circuit by irradiating the optical power converter with the laser via the fiber optic cable,
wherein a stray capacitance between the controller and the control supporting circuit is reduced to zero or nearly zero.

2. The method of claim 1, wherein the high voltage system is a power electronics circuit and wherein the control supporting circuit is a gate driver.

3. The method of claim 2, wherein the power electronics circuit comprises a switching module that includes switching devices controlled by the gate driver.

4. The method of claim 3, wherein the switching module includes a first switching module connected to a second switching module in series.

5. The method of claim 4, wherein the first switching module and the second switching module each comprise at least one wide bandgap transistor.

6. The method of claim 5, wherein the at least one wide bandgap transistor is rated at a voltage of 10 kV.

7. The method of claim 2, wherein the optical power converter supplies up to 20V at 5 W to the power electronics circuit.

8. The method of claim 1, wherein the laser source is a semiconductor diode.

9. The method of claim 8, further comprising tuning the laser source to a wavelength utilized by the optical power converter.

10. The method of claim 1, wherein the optical power converter is disposed adjacent to a heat sink.

11. The method of claim 1, wherein the fiber optic cable comprises a glass fiber optic cable.

12. A method of shutting down a laser source driver providing laser energy to an optical power converter, comprising:
connecting an optical power converter to a control supporting circuit coupled to a power electronics circuit, wherein the optical power converter is connected to a laser source via a fiber optic cable;
controlling, by a controller, a laser source driver to drive a laser source that provides a laser through the fiber optic cable;
controlling, by the controller, the control supporting circuit;
supplying power to the control supporting circuit by irradiating the optical power converter with the laser via the fiber optic cable;
connecting a second fiber optic cable from the controller to the control supporting circuit;
monitoring a feedback signal from the control supporting circuit to the controller on the second fiber optic cable; and
responsive to detecting a loss of the feedback signal, turning off, by the controller, the laser source driver.

13. The method of claim 12, wherein the controller turns off the laser source driver within 10 μs of detecting the loss of the feedback signal.

14. The method of claim 13, wherein the controller turns off the laser source driver utilizing a crowbar circuit coupled to the laser source.

15. The method of claim 12, wherein the control supporting circuit is a gate driver, and wherein the power electronics circuit is a switching module.

16. The method of claim 15, wherein the optical power converter supplies up to 20V at 5 W to the gate driver coupled to the switching module.
